(19) United States
(12) Patent Application Publication
(10) Pub. No.: US 2025/0254790 A1
(43) Pub. Date: Aug. 7, 2025

(54) GLASS CIRCUIT BOARD AND MANUFACTURING METHOD THEREOF AND IMAGING DEVICE

(71) Applicant: SONY SEMICONDUCTOR SOLUTIONS CORPORATION, KANAGAWA (JP)

(72) Inventor: SHUN MITARAI, KANAGAWA (JP)

(21) Appl. No.: 18/849,285

(22) PCT Filed: Mar. 14, 2023
(86) PCT No.: PCT/JP2023/009858

§ 371 Date: Sep. 20, 2024

(30) Foreign Application Priority Data
Mar. 30, 2022 (JP) 2022-056850

(51) Int. Cl. H05K 1/02; H01L 25/18; H05K 1/03; H05K 1/11; H05K 3/40; H10D 80/30; H10F 39/00; H10F 39/95

(52) U.S. Cl. CPC H05K 1/0271; H05K 1/0306; H05K 1/115; H05K 3/4076; H10F 39/811; H01L 25/18; H05K 2201/09581; H05K 2201/10121; H05K 2201/10151; H05K 2201/10212; H10D 80/30; H10F 39/95

(57) ABSTRACT

Provided is a glass circuit board and a manufacturing method thereof and an imaging device that achieve higher reliability. A glass circuit board including: a glass substrate serving as a core material including a first side, a second side located opposite from the first side, an outer end face located between the first side and the second side, and a through hole penetrating between the first side and the second side; an insulating first resin layer covering the first side; an insulating second resin layer covering the second side; a third resin layer that covers the inner surface of the through hole and is continuous with the first resin layer and the second resin layer; a fourth resin layer that covers the outer end face and is continuous with the first resin layer and the second resin layer; a first core wiring provided on the first side with the first resin layer interposed between the first core wiring and the first side; a second core wiring provided on the second side with the second resin layer interposed between the second core wiring and the second side; and a feed-through wiring provided on the inner surface of the through hole with the third resin layer interposed between the feed-through wiring and the inner surface.

### TECHNICAL FIELD

The present disclosure relates to a glass circuit board and a manufacturing method thereof and an imaging device.

### BACKGROUND ART

A glass interposer, a kind of multilayer circuit board, features a fine pattern because a semiconductor processing technique can be applied. A glass interposer can be designed for bumps with narrower pitches and finer wiring patterns. Furthermore, a glass interposer is promising as a substrate for semiconductor devices such as optical components and high-frequency components because of the high surface flatness and excellent insulating properties. For practical use of a glass interposer as a substrate for a semiconductor, it is important to keep the flatness of a glass substrate serving as a core material of the glass interposer and suppress the occurrence of cracks on the ends of the glass substrate.

In a known technique, scratches on an end face of a glass substrate are suppressed by covering the end face of the glass substrate with resin or the like (for example, see PTL 1). According to the technique disclosed in PTL 1, the reliability of the glass substrate is improved.

Moreover, in a known technique, resin is provided on the front side and the back side of a glass substrate and in through glass vias (TGVs) penetrating between the front side and the back side of the glass substrate, thereby preventing direct contact between the glass substrate and a wiring layer (for example, see NPL 1).

### CITATION LIST

### Patent Literature

[PTL 1]
WO 2021/200406

### Non Patent Literature

[NPL 1]
Yu-Hua Chen, Dyi-Chung Hu, Tzvy-Jang Tseng, “20”×20” panel size glass substrate manufacturing for 2.5D SiP application”, Electronic Components and Technology Conference (ECTC) 2015 IEEE 65th, pp. 1610-1615, 2015.

### SUMMARY

### Technical Problem

Glass interposers (hereinafter also referred to as glass circuit boards) that achieve higher reliability have been demanded.

The present disclosure has been made in view of such circumstances. An object of the present disclosure is to provide a glass circuit board and a manufacturing method thereof and an imaging device that achieve higher reliability.

### Solution to Problem

A glass circuit board according to one aspect of the present disclosure includes: a glass substrate serving as a core material including a first side, a second side located opposite from the first side, an outer end face located between the first side and the second side, and a through hole penetrating between the first side and the second side; an insulating first resin layer covering the first side; an insulating second resin layer covering the second side; a third resin layer that covers the inner surface of the through hole and is continuous with the first resin layer and the second resin layer; a fourth resin layer that covers the outer end face and is continuous with the first resin layer and the second resin layer; a first core wiring provided on the first side with the first resin layer interposed between the first core wiring and the first side; a second core wiring provided on the second side with the second resin layer interposed between the second core wiring and the second side; and a feed-through wiring provided on the inner surface of the through hole with the third resin layer interposed between the feed-through wiring and the inner surface.

With this configuration, the resin is disposed between the first core wiring, the second core wiring, and the feed-through wiring and the glass substrate. This can reduce an interface stress caused by a difference in the coefficient of thermal expansion between the wiring material and glass. Thus, the first core wiring and the second core wiring can be increased in thickness with wiring reliability. Moreover, the outer end face of the glass substrate is also covered with the resin layer. This can suppress scratches made on the outer end face, thereby increasing the strength of the glass substrate.

Furthermore, a tensile stress applied to the outer end of the glass substrate by cure shrinkage of the first resin layer and a tensile stress applied to the outer end of the glass substrate by cure shrinkage of the second resin layer can be canceled each other out via the resin layer covering the outer end face. This can suppress glass cracks caused by a stress applied from the front and back sides of glass to the end face, that is, the occurrence of Seware.

Hence, the glass circuit board capable of improving reliability can be provided.

A method for manufacturing a glass circuit board according to one aspect of the present disclosure, the method including: placing a glass substrate serving as a core material in a frame, the glass substrate including a first side, a second side located opposite from the first side, an outer end face located between the first side and the second side, and a through hole penetrating between the first side and the second side; supplying a resin material into the frame to form a first resin layer covering the first side, a second resin layer covering the second side, a third resin layer covering the inner surface of the through hole, and a fourth resin layer covering the outer end face of the glass substrate; forming a first core wiring provided on the first side with the first resin layer interposed between the first core wiring and the first side; forming a second core wiring provided on the second side with the second resin layer interposed between the second core wiring and the second side; forming a feed-through wiring provided in the through hole with the third resin layer interposed between the feed-through wiring and the through hole; and cutting the frame or the fourth resin layer in the thickness direction of the glass substrate after forming the first core wiring, the second core wiring, and the feed-through wiring.

Thus, the glass circuit board capable of improving reliability can be manufactured.

An imaging device according to one aspect of the present disclosure includes a glass circuit board, and an imaging element attached to the glass circuit board. The glass circuit board includes: a glass substrate serving as a core material including a first side, a second side located opposite from the first side, an outer end face located between the first side and the second side, and a through hole penetrating between the first side and the second side; an insulating first resin layer covering the first side; an insulating second resin layer covering the second side; a third resin layer that covers the inner surface of the through hole and is continuous with the first resin layer and the second resin layer; a fourth resin layer that covers the outer end face and is continuous with the first resin layer and the second resin layer; a first core wiring provided on the first side with the first resin layer interposed between the first core wiring and the first side; a second core wiring provided on the second side with the second resin layer interposed between the second core wiring and the second side; and a feed-through wiring provided on the inner surface of the through hole with the third resin layer interposed between the feed-through wiring and the inner surface. Thus, the imaging element is attached to the glass circuit board capable of improving reliability, thereby improving the reliability of the imaging device.

### BRIEF DESCRIPTION OF DRAWINGS

FIG. 1 is a cross-sectional view illustrating a configuration example of a glass circuit board according to a first embodiment of the present disclosure.

FIG. 2 is a cross-sectional view illustrating a method for manufacturing the glass circuit board according to the first embodiment of the present disclosure in the order of steps.

FIG. 3 is a cross-sectional view illustrating the method for manufacturing the glass circuit board according to the first embodiment of the present disclosure in the order of steps.

FIG. 4 is a cross-sectional view illustrating the method for manufacturing the glass circuit board according to the first embodiment of the present disclosure in the order of steps.

FIG. 5 is a plan view illustrating the method for manufacturing the glass circuit board according to the first embodiment of the present disclosure in the order of steps.

FIG. 6 is a plan view illustrating the method for manufacturing the glass circuit board according to the first embodiment of the present disclosure in the order of steps.

FIG. 7 is a plan view illustrating the method for manufacturing the glass circuit board according to the first embodiment of the present disclosure in the order of steps.

FIG. 8 is a cross-sectional view illustrating configuration example 1 of a through hole according to a second embodiment of the present disclosure.

FIG. 9 is a cross-sectional view illustrating configuration example 2 of the through hole according to the second embodiment of the present disclosure.

FIG. 10 is a cross-sectional view illustrating configuration example 3 of the through hole according to the second embodiment of the present disclosure.

FIG. 11 is a cross-sectional view illustrating configuration example 1 of a through hole and an embedded member according to a third embodiment of the present disclosure.

FIG. 12 is a cross-sectional view illustrating configuration example 2 of the through hole and the embedded member according to the third embodiment of the present disclosure.

FIG. 13 is a cross-sectional view illustrating configuration example 3 of the through hole and the embedded member according to the third embodiment of the present disclosure.

FIG. 14 is a plan view illustrating a configuration example of a glass circuit board according to a fourth embodiment of the present disclosure.

FIG. 15 is a cross-sectional view illustrating a configuration example of an imaging device according to a fifth embodiment of the present disclosure.

FIG. 16 is a cross-sectional view illustrating a configuration example of an imaging device according to a sixth embodiment of the present disclosure.

### DESCRIPTION OF EMBODIMENTS

Embodiments of the present disclosure will be described below with reference to the drawings. In the descriptions of the drawings referred to in the following description, the same or similar portions will be denoted by the same or similar reference signs. However, it should be noted that the drawings are schematic, and the relationships between thicknesses and planar dimensions, ratios of thicknesses of respective layers, and the like are different from actual ones. Therefore, specific thicknesses and dimensions should be determined in light of the following descriptions. In addition, it goes without saying that the drawings include portions having different dimensional relationships and ratios.

It is to be understood that the definitions of directions such as upward and downward in the following description are merely definitions provided for the convenience of explanation and are not intended to limit the technical ideas of the present disclosure. For example, it is obvious that when an object is observed after being rotated by 90 degrees, up-down is converted into and interpreted as left-right, and when an object is observed after being rotated by 180 degrees, up-down is interpreted as being inverted.

Furthermore, in the following description, “plan view” means a view in the thickness direction of a glass substrate 1 (in other words, in the direction of the normal to a front side 1a or a back side 1b of the glass substrate 1), which will be described later.

### First Embodiment

### (Configuration Example)

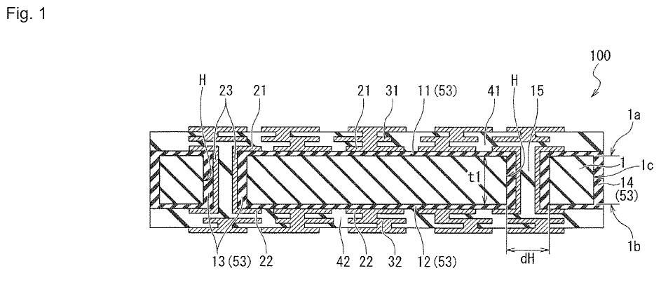

FIG. 1 is a cross-sectional view illustrating a configuration example of a glass circuit board 100 according to a first embodiment of the present disclosure. As illustrated in FIG. 1, the glass circuit board 100 according to the first embodiment of the present disclosure includes the glass substrate 1 serving as a core material, an insulating first resin layer 11 covering the front side (an example of “first side” of the present disclosure) of the glass substrate 1, an insulating second resin layer 12 covering the back side (an example of “second side” of the present disclosure) of the glass substrate 1, a third resin layer 13 that covers the inner surface of a through hole H penetrating between the front side and the back side of the glass substrate 1 and is continuous with the first resin layer 11 and the second resin layer 12, and a fourth resin layer 14 that covers an outer end face located between the front side and the back side of the glass substrate 1 and is continuous with the first resin layer 11 and the second resin layer 12.

The glass circuit board 100 further includes a first core wiring 21 provided on the front side 1a of the glass substrate 1 with the first resin layer 11 interposed between the first core wiring 21 and the front side 1a, a second core wiring 22 provided on the back side 1b of the glass substrate 1 with the second resin layer 12 interposed between the second core wiring 22 and the back side 1b, a feed-through wiring 23 provided on the inner surface of the through hole H with the third resin layer 13 interposed between the feed-through wiring 23 and the inner surface, and an embedded resin 15 in the through hole H. A feed-through wiring 13 is located between the third resin layer 13 and the embedded resin 15.

The glass circuit board 100 further includes a first multilayer wiring 31 that is provided near the front side 1a of the glass substrate 1, a second multilayer wiring 32 provided near the back side 1b of the glass substrate 1, a first interlayer insulating film 41 provided near the front side 1a of the glass substrate 1, and a second interlayer insulating film 42 provided near the back side 1b of the glass substrate 1.

Portions constituting the glass circuit board 100 will be described in detail. The glass substrate 1 has the front side 1a, the back side 1b located opposite from the front side 1a, and an outer end face 1c located between the front side 1a and the back side 1b. The front side 1a, the back side 1b, and the outer end face 1c of the glass substrate 1 are flat (or almost flat). The outer end face 1c is provided perpendicularly (or almost perpendicularly) to the front side 1a and the back side 1b. For example, the glass substrate 1 is rectangular in plan view.

The outer end face 1c is located on an edge of the rectangle. A thickness ti (specifically a distance between the front side 1a and the back side 1b) of the glass substrate 1 is, for example, 0.3 mm to 1.0 mm and is not particularly limited.

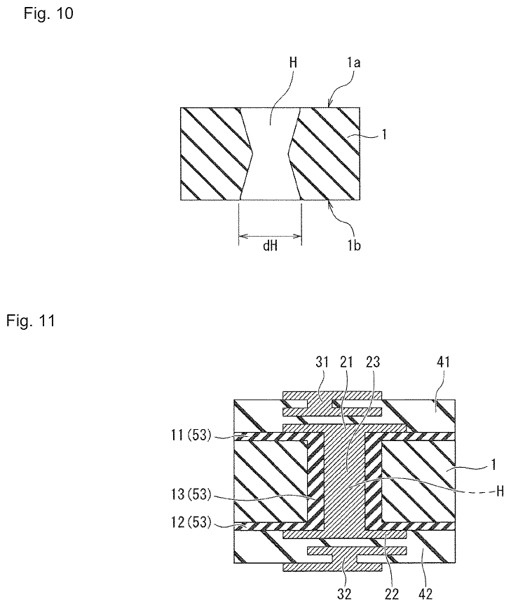

The glass substrate 1 includes the through hole H penetrating between the front side 1a and the back side 1b. For example, the through hole H is circular in plan view. A diameter dH of the through hole H is, for example, 50 μm to 300 μm and is not particularly limited. The diameter dH of the through hole H may be uniform (or almost uniform) from the front side 1 to the back side 1b of the glass substrate 1 or may gradually change in the thickness direction of the glass substrate 1 (see FIGS. 9 and 10 described later).

The first resin layer 11, the second resin layer 12, the third resin layer 13, the fourth resin layer 14, and the embedded resin 15 are made of an insulating resin material such as epoxy resin.

The first resin layer 11 is disposed as a stress buffer layer between the glass substrate 1 and the first core wiring 21. Moreover, the second resin layer 12 is disposed as a stress buffer layer between the glass substrate 1 and the second core wiring 22. Furthermore, the third resin layer 13 is disposed as a stress buffer layer between the glass substrate 1 and the feed-through wiring 23. With this configuration, a stress applied between the glass substrate 1 and the first core wiring 21 (e.g., a stress caused by a difference in thermal expansion between the glass substrate 1 and the first core wiring 21) can be reduced by deformation of the first resin layer 11. Likewise, a stress applied between the glass substrate 1 and the second core wiring 22 and a stress applied between the glass substrate 1 and the feed-through wiring 23 can be reduced by deformation of the second resin layer 12 and the third resin layer 13, respectively. This can improve the reliability of the first core wiring 21, the second core wiring 22, and the feed-through wiring 23.

Moreover, the front side 1a, the back side 1b, and the outer end face 1c of the glass substrate 1 are continuously covered with resin. The first resin layer 11 provided near the front side 1a of the glass substrate 1 and the second resin layer 12 provided near the back side 1b have structures connected via the fourth resin layer 14 provided on the outer end face 1c. Thus, a tensile stress applied to the outer end of the glass substrate 1 by a cure shrinkage force of the first resin layer 11 (a stress pulling the outer end of the glass substrate 1 upward in FIG. 1) and a tensile stress applied to the outer end of the glass substrate 1 by a cure shrinkage force of the second resin layer 12 (a stress pulling the outer end of the glass substrate 1 downward in FIG. 1) are canceled each other out via the fourth resin layer 14. The tensile stress applied upward and the tensile stress applied downward are canceled each other out, thereby reducing the occurrence of cleavage vertically from small scratches on the outer end face of the glass substrate 1 (that is, a phenomenon called Seware).

Moreover, the first resin layer 11 and the second resin layer 12 have structures connected via the third resin layer 13 provided on the inner surface of the through hole H. Thus, in addition to the fourth resin layer 14, the third resin layer 13 contributes to cancellation of a tensile force caused by cure shrinkage of the first resin layer 11 and a tensile force caused by cure shrinkage of the second resin layer 12.

As described above, the first core wiring 21 and the second core wiring 22 that are located closest to the glass substrate 1 can be more reliable, and tensile stresses caused by cure shrinkage of the first resin layer 11 and the second resin layer 12, which are the base layers of the core wirings, can be canceled each other out to suppress the occurrence of Seware. Thus, the first core wiring 21 and the second core wiring 22 can be easily increased in thickness.

The first resin layer 11, the second resin layer 12, the third resin layer 13, the fourth resin layer 14, and the embedded resin 15 are made of, for example, an insulating resin material such as epoxy resin, filler-containing epoxy resin, or silicone resin. From the viewpoint of Seware suppression or from the viewpoint of ease of manufacturing, the first resin layer 11, the second resin layer 12, the third resin layer 13, and the fourth resin layer 14 are preferably made of the same resin material. Thus, when the first resin layer 11 and the second resin layer 12 cure and shrink, the third resin layer 13 and the fourth resin layer 14 also cure and shrink in the same manner, which may more effectively cancel out a tensile stress caused by cure shrinkage of the first resin layer 11 and a tensile stress caused by cure shrinkage of the second resin layer 12.

The embedded resin 15, the first interlayer insulating film 41, and the second interlayer insulating film 42 are made of an insulating resin material such as epoxy resin or glass epoxy resin. The embedded resin 15, the first interlayer insulating film 41, and the second interlayer insulating film 42 may be made of the same material or different materials.

The first core wiring 21, the second core wiring 22, the feed-through wiring 23, the first multilayer wiring 31, and the second multilayer wiring 32 are made of, for example, a low-resistance metallic material such as copper. The first core wiring 21, the second core wiring 22, the feed-through wiring 23, the first multilayer wiring 31, and the second multilayer wiring 32 may be made of the same material or different materials.

### (Manufacturing Method)

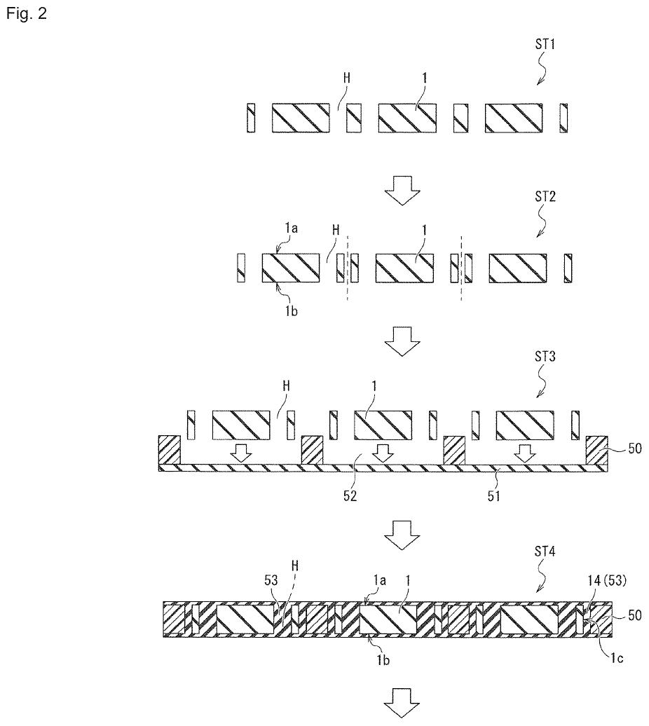

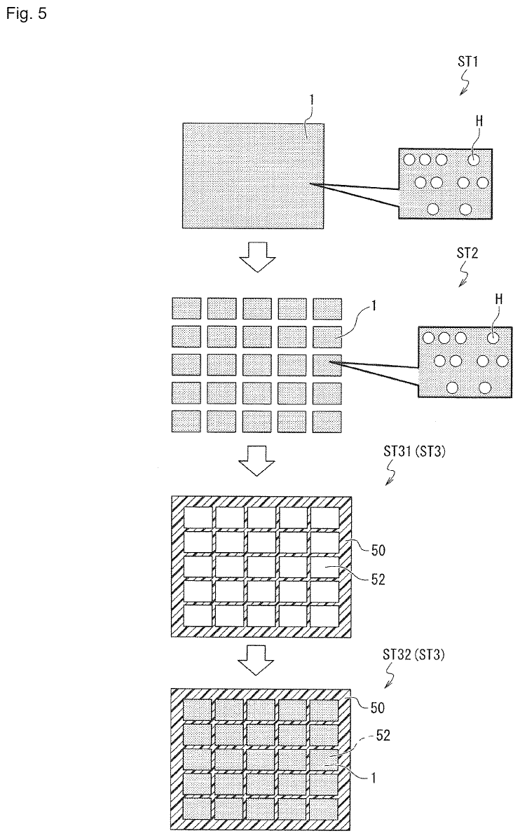

A method for manufacturing the glass circuit board 100 illustrated in FIG. 1 will be described below with reference to cross-sectional views and plan views. FIGS. 2 to 4 are cross-sectional views illustrating the method for manufacturing the glass circuit board 100 according to the first embodiment of the present disclosure in the order of steps. FIGS. 5 to 7 are plan views illustrating the method for manufacturing the glass circuit board 100 according to the first embodiment of the present disclosure in the order of steps.

In FIGS. 2 to 7, step ST1 shows a TGV opening step, step ST2 shows a glass fragmentation step, step ST3 shows a mounting step on a frame substrate, step ST4 shows a glass core embedding step, step ST5 shows an inner through hole opening step, step ST6 shows a core wiring forming step, step ST7 shows a wiring-insulating-layer forming step, step ST8 shows an upper wiring forming step, and steps ST9 and ST9A show a glass interposer fragmentation step. These steps will be described below.

First, the glass substrate 1 serving as a core material is prepared, and then through holes H referred to as TGVs are formed with desired dimensions at desired positions on the glass substrate 1 (step ST1 in FIGS. 2 and 5). The glass substrate 1 with the formed through holes H is cut into pieces with dimensions smaller than the outside shape of the completed glass circuit board (step ST2 in FIGS. 2 and 5). The dimensions at this time are calculated backward from the embedding width of a frame substrate 50 and an embedded resin 53 (in other words, a clearance between the frame substrate 50 and the glass substrate 1), which will be described later. The frame substrate 50 and the embedded resin 53 are left on the end of the completed glass circuit board.

The shape of the glass substrate 1 in plan view (hereinafter referred to as a planar shape) is, for example, rectangular after being cut into pieces. The planar shape of the glass substrate 1 is not limited to a rectangle after being cut into pieces. The glass substrate 1 may have any shapes such as rectangles with rounded corners. The method of dividing the substrate is not particularly limited if glass is cut by, for example, blade dicing or laser. After the substrate is divided into pieces, microcracks on the cut face may be removed by etching with hydrofluoric acid or the like.

Meanwhile, cavity processing (hollowing) is performed to embed the pieces of the glass substrate 1 into a glass epoxy substrate serving as a workpiece to be subjected to a multilayer wiring step, which will be described later (step ST31 of FIG. 5). The processed glass epoxy substrate will be referred to as a frame substrate. The frame substrate 50 is an example of “frame” of the present disclosure. The hollowing dimensions of the frame substrate 50 are values obtained by adding the embedding width of the embedded resin 53 (=a clearance upon embedding) to the pieces of the glass substrate 1.

The embedding width of the embedded resin 53 can be determined from various factors such as the tolerance of the fragmentation processing of the glass substrate 1, the tolerance of the cavity processing of the frame substrate 50, the fluidity of the embedded resin 53, and a resin film thickness required to protect the end face of the glass substrate 1. In the study of the present disclosers, embedding widths between 30 μm and 200 μm were used but are not limited thereto. The processing method is not particularly limited if a glass epoxy substrate is cut according to a technique using a router or laser.

Subsequently a film 51 for mounting a glass substrate is attached to the bottom of the frame substrate 50 to form a pocket structure 52, and then the pieces of the glass substrate 1 are mounted into the pocket structure 52 (step ST3 of FIG. 2, step ST32 of FIG. 5). The film 51 may be used temporarily to fix the glass substrate 1. In this case, the surface to be attached to the frame substrate 50 is preferably peeled off without leaving any adhesive residue after the resin is embedded. The film 51 may remain on the glass circuit board until the end of the process, rather than temporarily In such cases, a resin film made of the same material as the embedded resin 53 may be used as the film 51.

The method for mounting the glass substrate 1 using, for example, a chip mounter or a die bonder is not particularly limited. Since the accuracy of the mounting position determines a clearance in the subsequent steps (or requires one-by-one processing on the pieces), a high-precision method is desirably used. The pieces of the glass substrate 1 being mounted may be positioned with respect to the outside shapes of the cavities (that is, the pocket structure 52) and the outside shapes of the pieces of the glass substrate 1. For the same reason as the mounting method, the positioning may be performed by aligning marks formed on the frame substrate 50 and the through holes H serving as marks in the pieces of the glass substrate 1.

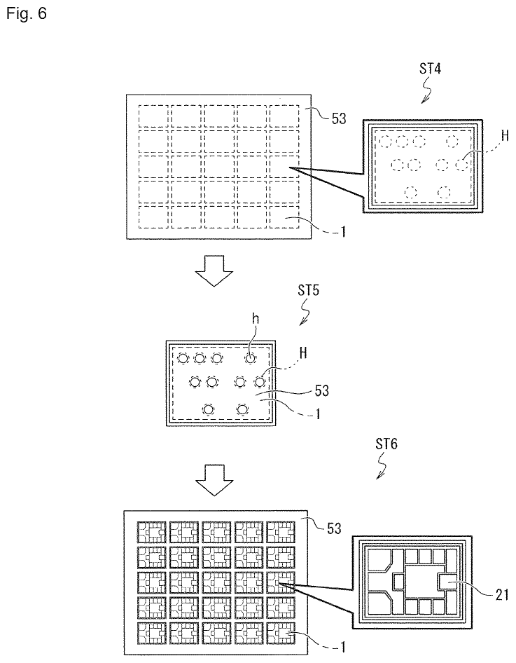

For the workpiece in this state, the embedded resin 53 is first supplied from the front side 1a of the glass substrate 1 (that is, the side not covered with the film 51) to embed the pieces of the glass substrate 1. Thus, a clearance between the glass substrate 1 and the frame substrate 50 and the cavities in the through holes H are filled with the embedded resin 53 (step ST4 of FIGS. 2 and 6). The fourth resin layer 14 fills a clearance between the outer end face 1c of the glass substrate 1 and the frame substrate 50.

The embedded resin 53 may be supplied in any form, e.g., in liquid or film form, according to a method such as printing or lamination with no particular restrictions. However, in view of the transmission characteristics and reliability of the wiring and affinity with the interlayer insulating film, a laminate of ABF (Ajinomoto Build-up Film) manufactured by Ajinomoto Fine-Techno Co., Inc. is used as an example.

For the back side 1b of the glass substrate 1, if the film 51 is temporarily used, the same resin as the embedded resin 53 supplied from the front side 1a is supplied from the back side 1b of the glass substrate 1 after the film 51 is peeled off. If the film 51 is left on the glass circuit board until the end of the process, rather than temporarily step ST4 is completed when the embedded resin 53 is supplied from the front side 1a of the glass substrate 1 to complete embedding.

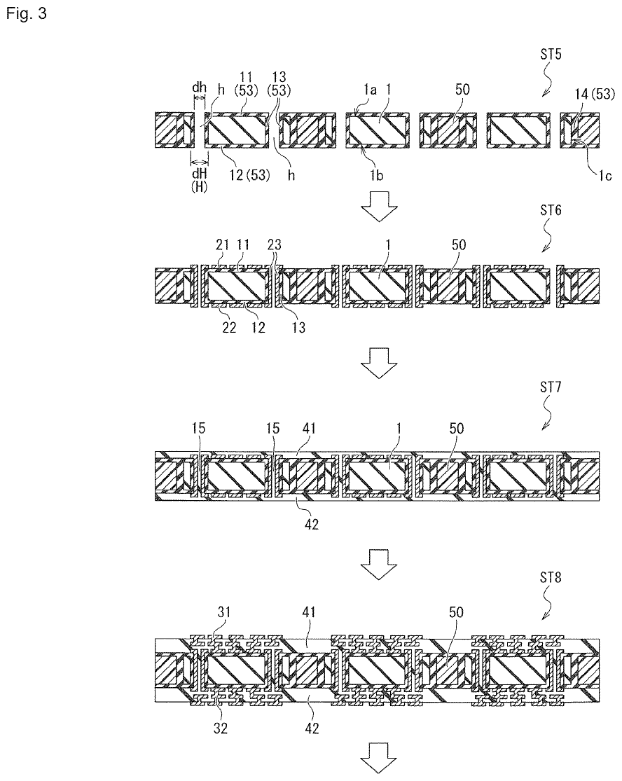

Subsequently inner through holes h are formed on the embedded resin 53 in the through holes H (step ST5 of FIGS. 3 and 6). The inner through hole h is a part of the through hole H. The inner through holes h may be formed by any method such as mechanical drilling or laser. Since a diameter dh of the inner through hole h is smaller than a diameter dH of the through hole H, through holes are more desirably formed by laser capable of forming fine through holes. According to this manufacturing method, the side walls of the inner through holes h are all covered with the embedded resin 53, thereby preventing the glass substrate 1 from being exposed from the resin.

In the embedded resin 53 having the inner through holes h, a part covering front side of the glass substrate 1 serves as the first resin layer 11, a part covering the back side 1b of the glass substrate 1 serves as the second resin layer 12, a part covering the inner surface of the through hole H serves as the third resin layer, and a part covering the outer end face of the glass substrate 1 serves as the fourth resin layer 14.

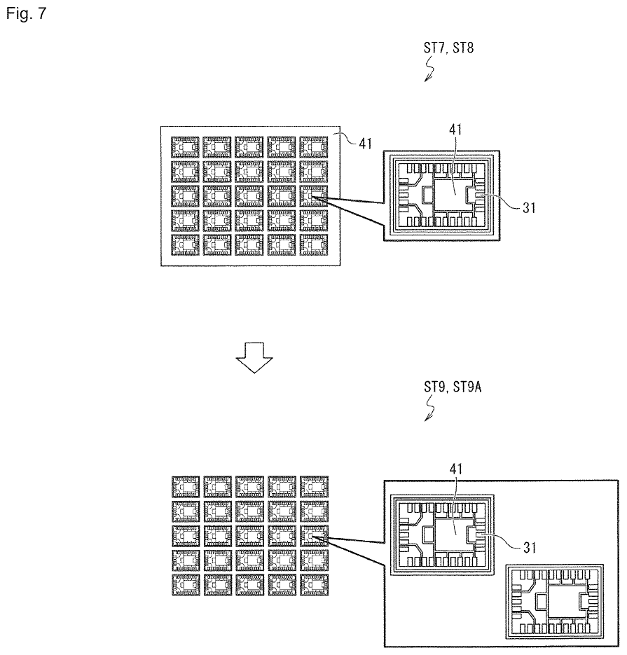

Thereafter, metallization of the inner through holes h and formation of the core wirings on the front and back sides are performed simultaneously to form the first core wiring 21, the second core wiring 22, and the feed-through wiring 23 (step ST6 in FIGS. 3 and 6). Subsequently the insulating layers, the vias, and the wirings are repeatedly formed until a desired number of layers are obtained, so that the embedded resin 15, the first multilayer wiring 31, the first interlayer insulating film 41, the second multilayer wiring 32, and the second interlayer insulating film 42 are formed (steps ST7 and ST8 in FIGS. 3 and 7). The embedded resin 15 may be formed concurrently with at least one of the first interlayer insulating film 41 and the second interlayer insulating film 42.

The process in steps ST6 to ST8 can be performed using ordinary methods for printed circuit boards, for example, the semi-additive process (SAP), the modified SAP (MSAP), and a subtractive process. In addition, on each of the front side 1a and the back side 1b of the glass substrate 1, solder resist is formed on the top layer and surface terminals are treated (Ni/Au plating, OSP; Organic Solderability Preservative treatment) as necessary.

Finally the glass circuit board is cut into pieces with desired dimensions. The cut surface may be the embedded resin 53 between the frame substrate 50 and the glass substrate 1 (step ST9 of FIG. 7) or the frame substrate 50 (step ST9A of FIG. 7). In the former case, that is, in step ST9, the fourth resin layer 14 is cut in the thickness direction of the glass substrate 1. In the latter case, that is, in step ST9A, the frame substrate 50 is cut in the thickness direction of the glass substrate 1. In the latter case, the frame substrate 50 partially remains on the outer periphery of the glass circuit board 100. Through the above steps, the glass circuit board 100 in FIG. 1 is completed.

### (Characteristics of Embedded Resin)

The embedded resin 53 (that is, the first resin layer 11, the second resin layer 12, the third resin layer 13, and the fourth resin layer 14) described in the manufacturing method is desirably a material having a low Young's modulus. This is because the embedded resin 53 acts as a stress buffer layer between the first core wiring 21, the second core wiring 22, and the feed-through wiring 23 and the glass substrate 1. Moreover, the stress buffer function is exhibited by strain deformation of the layer, and thus the material desirably has a large elongation at the same time to prevent the deformation from breaking the material. The specific numeric values are design factors depending upon the structure or layout and are approximately a Young's modulus of 8 GPa or less (more desirably 1 GPa or less) and an elongation of 2% or more (more desirably 10% or more). From the same viewpoint, the material desirably has a coefficient of thermal expansion between 3 (glass) and 17 (copper) ppm/° C.

The embedded resin 15, the first interlayer insulating film 41, and the second interlayer insulating film 42 may be made of the same insulating resin material as the embedded resin 53 (that is, the first resin layer 11, the second resin layer 12, the third resin layer 13, and the fourth resin layer 14). Thus, the amount of displacement relative to a temperature is constant between the embedded resin 15, the first interlayer insulating film 41, and the second interlayer insulating film 42 and the embedded resin 53. This can suppress a stress increased by a difference in the amount of displacement.

### Advantageous Effect of First Embodiment

As described above, the glass circuit board 100 according to the first embodiment of the present disclosure includes the glass substrate 1 serving as a core material including the front side 1a, the back side 1b located opposite from the front side 1a, the outer end face 1c located between the front side 1a and the back side 1b, and the through holes H penetrating between the front side 1a and the back side 1b. The glass circuit board 100 further includes the insulating first resin layer 11 covering the front side 1a of the glass substrate 1, the insulating second resin layer 12 covering the back side 1b, the third resin layer 13 that covers the inner surface of the through hole H and is continuous with the first resin layer 11 and the second resin layer 12, the fourth resin layer 14 that covers the outer end face 1c and is continuous with the first resin layer 11 and the second resin layer 12, the first core wiring 21 provided on the front side 1a with the first resin layer 11 interposed between the first core wiring 21 and the front side 1a, the second core wiring 22 provided on the back side 1b with the second resin layer 12 interposed between the second core wiring 22 and the back side 1b, and the feed-through wiring 23 provided on the inner surface of the through hole H with the third resin layer 13 interposed between the feed-through wiring 23 and the inner surface.

With this configuration, the first resin layer 11 is disposed between the first core wiring 21 and the glass substrate 1, the second resin layer 12 is disposed between the second core wiring 22 and the glass substrate 1, and the third resin layer 13 is disposed between the feed-through wiring 23 and the glass substrate 1. This can reduce an interface stress caused by a difference in the coefficient of thermal expansion between the wiring material and glass. Thus, the first core wiring 21 and the second core wiring 22 can be increased in thickness with wiring reliability.

Moreover, the outer end face 1c of the glass substrate 1 is covered with the fourth resin layer 14. This can protect the outer end face 1c and suppress scratches made on the outer end face 1c. Hence, the strength of the glass substrate can be improved.

Furthermore, a tensile stress applied to the outer end of the glass substrate 1 by cure shrinkage of the first resin layer 11 and a tensile stress applied to the outer end of the glass substrate 1 by cure shrinkage of the second resin layer 12 can be canceled each other out via the fourth resin layer 14. Thus, even when the first resin layer 11 and the second resin layer 12 have large thicknesses, the occurrence of Seware can be suppressed.

Hence, the glass circuit board 100 capable of improving reliability can be provided.

The effects of the first embodiment will be specifically described below using comparative examples.

In the technique disclosed in PTL 1 (hereinafter also referred to as comparative example 1), the core wiring is formed directly on the glass substrate, and thus an interface stress caused by a difference in the coefficient of thermal expansion between the glass substrate and the wiring material is likely to deteriorate wiring reliability. If the core wiring has a large thickness, the risk is likely to increase. For example, in order to provide a so-called stacked-via, which is a via provided on a TGV, a lid plating needs to be formed on the TGV. The lid plating increases the thickness of the wiring. Since a stress is applied to an interface with the glass substrate according to the thicknesses of the lid plating and the core wiring, the wiring reliability may decrease.

In the technique disclosed in NPL 1 (hereinafter also referred to as comparative example 2), the structure is designed such that the glass substrate and the wiring material are not placed in direct contact with each other, thereby easily obtaining wiring reliability. However, the end face of the glass substrate is exposed and thus is likely to be scratched, so that the strength of the glass substrate may decrease.

In comparative example 2, the resin is formed on the glass substrate and is injected into the TGV at the same time. In order to fully fill the TGV with the resin, a required amount of embedding depends upon the diameter and depth of the TGV, so that the resin formed on the glass substrate is likely to be thick. In comparative example 2, a stress caused by the thick resin and the multilayer wiring and the interlayer insulating film that are formed on the resin is concentrated on the end face of the glass substrate. Thus, in comparative example 2, a larger tensile stress is applied to the end face of the glass substrate from above and below, thereby easily inducing cracks (i.e., SEWARE) from the end face of the glass substrate in the horizontal direction of the glass substrate. In order to prevent SEWARE, for example, the step of covering the end faces of pieces of the glass substrate with resin may be added. In this case, the step of forming resin to cover the end face of the glass substrate needs to be prepared in addition to the step of forming resin on the glass substrate and into the TGV, leading to higher cost.

In contrast, the glass circuit board 100 according to the first embodiment of the present disclosure includes the glass substrate 1 that has the through holes H and serves as a core material, the first resin layer 11 between the front side 1a of the glass substrate 1 and the first core wiring 21, the second resin layer 12 between the back side 1b of the glass substrate 1 and the second core wiring 22, the third resin layer 13 between the inner surface of the through hole H and the feed-through wiring 23, and the fourth resin layer 14 covering the outer end face 1c of the glass substrate 1. For example, the first resin layer 11, the second resin layer 12, the third resin layer 13, and the fourth resin layer 14 are made of the same insulating resin material. The first resin layer 11, the second resin layer 12, the third resin layer 13, and the fourth resin layer 14 are simultaneously formed in the same step.

Thus, the glass circuit board 100 according to the first embodiment of the present disclosure improves the reliability of all the glass boundary regions of the glass substrate 1 (the glass end face, a core-wiring interface, a TGV) according to, for example, almost the same process (only via openings are added to resin) as in comparative example 1.

Moreover, the glass circuit board 100 according to the first embodiment of the present disclosure includes the end face protecting structure using the fourth resin layer 14 and thus can reduce a stress concentrating on the end face of the glass substrate according to an increase in the thickness of the interlayer insulating film, the increase being inevitable in the structure of comparative example 2, and the probability of occurrence of Seware due to the stress concentration.

Furthermore, the glass circuit board 100 according to the first embodiment of the present disclosure has the resin layer between the glass substrate 1 and all the wirings, thereby forming the thick wirings while ensuring wiring reliability.

Thus, the reliability margin of a stacked-via structure (for example, see FIG. 13 described later) using lid plating extends to improve the high-speed transmission characteristics of the glass circuit board 100. Furthermore, in a use where integrated passive devices (IPDs) are formed in the glass circuit board 100, the Q value of an inductor is improved by increasing the thickness of the wiring.

Thus, the range of uses of the glass circuit board 100 can be expected to increase with enhanced performance.

### Second Embodiment

In the example of the first embodiment, the inner surface of the through hole H referred to as a TGV is perpendicular to the front side 1a and the back side 1b of the glass substrate 1. However, in the present disclosure, the processing shape of the through hole H is not limited thereto.

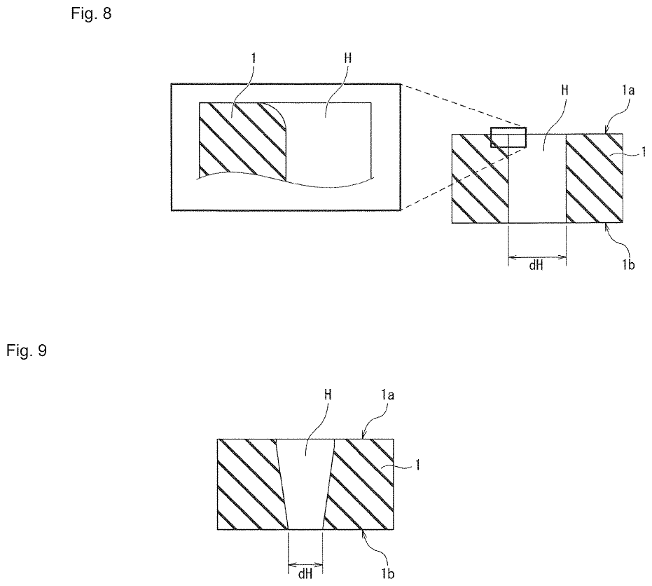

FIGS. 8 to 10 are cross-sectional views illustrating configuration examples 1 to 3 of a through hole H according to a second embodiment of the present disclosure. As illustrated in FIG. 8, the through hole H may have a rounded opening edge at a front side 1a of a glass substrate 1. Thus, a stress concentration decreases between a first core wiring 21 (see FIG. 1) and the opening edge of the through hole H, which is desirable from the viewpoint of reliability. Likewise, the through hole H may have a rounded opening edge at a back side 1b of the glass substrate 1. Thus, a stress concentration decreases between a second core wiring 22 (see FIG. 1) and the opening edge of the through hole H, which is desirable from the viewpoint of reliability.

As illustrated in FIG. 9, the through hole H may be tapered such that a diameter dH gradually decreases from the front side 1a to the back side 1b of the glass substrate 1. Alternatively the through hole H may be tapered such that the diameter dH gradually decreases from the back side 1b to the front side 1a of the glass substrate 1.

As illustrated in FIG. 10, the through hole H may have a constricted shape such that the diameter dH gradually decreases from the front side 1a and the back side 1b of the glass substrate 1 to the center in the thickness direction of the glass substrate 1 and the diameter dH decreases to a minimum at the center.

In the embodiment of the present disclosure, the method for machining the through hole H is not particularly limited. From the viewpoint of reliability it is desirable to employ a method in which damage during machining is not left by aftertreatment using hydrofluoric acid (HF) or a mixed acid thereof during machining or after machining penetration. The round shape of the opening edge of the through hole H in FIG. 8 can be obtained by for example, aftertreatment using hydrofluoric acid (HF) or a mixed acid thereof after the machining penetration.

### Third Embodiment

In the first embodiment, the embedded resin 15 is a member embedded into the through hole H to cover the feed-through wiring 23. Moreover, the first embodiment described that the embedded resin 15 is formed concurrently with, for example, at least one of the first interlayer insulating film 41 and the second interlayer insulating film 42 (in other words, the embedded resin 15 is made of the same insulating resin material as at least one of the first interlayer insulating film 41 and the second interlayer insulating film 42). However, the material embedded into the through hole H is not limited thereto.

FIGS. 11 to 13 are cross-sectional views illustrating first to third configuration examples of a through hole H and an embedded member filling the through hole H according to a third embodiment of the present disclosure. As illustrated in FIG. 11, the through hole H may be filled with a feed-through wiring 23. For example, the through hole H may be metallized as filled plating or may be filled with another material such as conductive paste. Thus, the resistance of the feed-through wiring 23 can be reduced (in other words, the resistance of a via can be reduced).

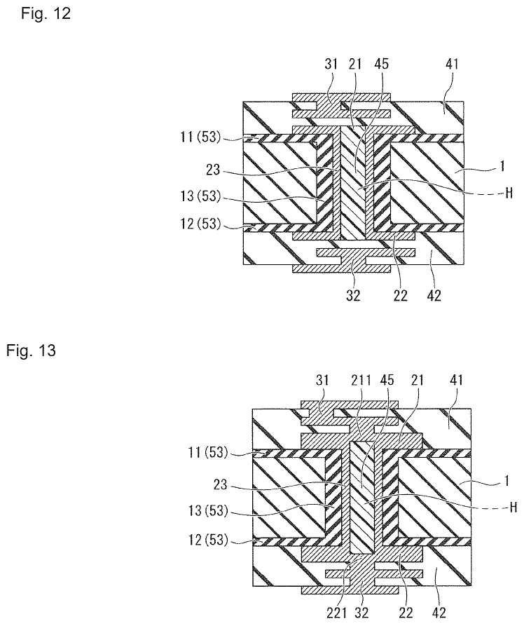

As illustrated in FIG. 12, the through hole H may be filled with an embedded resin 45 different from a first interlayer insulating film 41 and a second interlayer insulating film 42. The embedded resin 45 is composed of an insulating resin material or a conductive resin material that is different from the embedded resin 15 (in other words, the same insulating resin material as at least one of the first interlayer insulating film 41 and the second interlayer insulating film 42) of the first embodiment in characteristics such as a Young's modulus, an elongation, and the coefficient of thermal expansion. If the embedded resin 45 is made of a conductive resin material, the resistance of the via can be reduced.

If the embedded resin 45 is composed of a conductive resin material, a stacked-via structure as illustrated in FIG. 13 can be constructed by forming conductive lid portions 211 and 221 through plating or the like on the embedded resin 45 (i.e., by adding lid plating). The conductive lid portions 211 and 221 are made of, for example, metals such as copper (Cu). The conductive lid portions 211 and 221 are disposed on the respective upper and lower opening ends of the through hole H and cover the embedded resin 45. The through hole H serving as a via is filled with the conductive embedded resin 45, thereby extending the reliability margin of the stacked-via structure.

The stacked-via structure enables the wiring connected to vias to extend linearly in the upward (or downward) direction of the via, thereby shortening the wiring length and reducing the number of wiring bending points. This can improve the transmission characteristics of high-frequency signals.

Furthermore, in a use where integrated passive devices (IPDs) are formed in the substrate, the Q value of an inductor is improved by increasing the thickness of the wiring. Thus, the range of uses of the glass circuit board 100 can be expected to increase with enhanced performance.

The conductive lid portion 211 near a front side 1a of a glass substrate 1 is formed by, for example, forming an insulating resin layer as the first interlayer insulating film 41 after forming the embedded resin 45, patterning the insulating resin layer to form an opening with the embedded resin 45 serving as the bottom in the upper portion of the through hole H, applying metallic plating to form a metallic layer (e.g., a Cu layer) on the insulating resin layer having the opening, and patterning the metallic layer into a lid shape. The conductive lid portion 221 near a back side 1b can also be formed by the same method.

### Fourth Embodiment

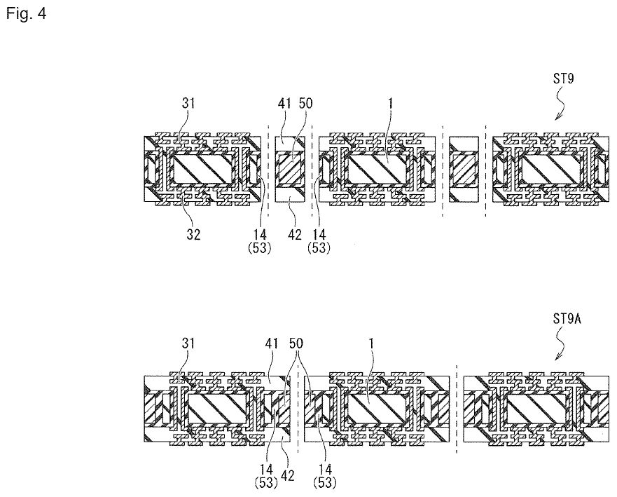

In the first embodiment, the frame substrate 50 may be left on the outer periphery of the glass circuit board 100 after the glass circuit board 100 is divided into pieces (see step ST9A of FIG. 4). If the frame substrate 50 is left on the outer periphery of the glass circuit board 100, the frame substrate 50 may have another function in addition to the protection of the outer end face of the glass substrate 1.

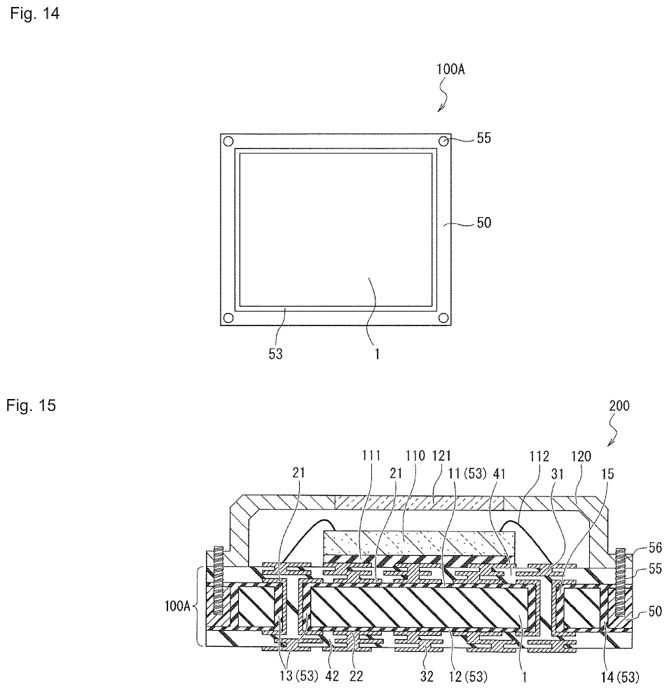

FIG. 14 is a plan view illustrating a configuration example of a glass circuit board 100A according to a fourth embodiment of the present disclosure. As illustrated in FIG. 14, the glass circuit board 100A may have fastening holes 55 on a frame substrate 50. The fastening holes 55 can be used for fastening the glass circuit board 100A to a cabinet or attaching a protective cover to the glass circuit board 100A. The placement of the fastening holes 55 on the frame substrate 50 applies a fastening torque to a region other than a glass substrate 1 made of a brittle material, thereby avoiding a failure in the form of actual use. Moreover, if a wiring region that does not require glass properties is placed on a region other than the frame substrate 50, a glass area can be reduced to reduce costs.

### Fifth Embodiment

FIG. 15 is a cross-sectional view illustrating a configuration example of an imaging device 200 according to a fifth embodiment of the present disclosure. As illustrated in FIG. 15, the imaging device 200 according to the fifth embodiment of the present disclosure includes the glass circuit board 100A described in the fourth embodiment, an imaging element 110 mounted on the glass circuit board 100A, and a protective cover 120 that is attached to the glass circuit board 100A to cover the imaging element 110.

The imaging element 110 is, for example, a CMOS image sensor chip with the light receiving surface placed faceup. The imaging element 110 is bonded on the glass circuit board 100A with an adhesive 111 and is electrically connected to the bonding pads of a first multilayer wiring 31 via bonding wires 112.

The protective cover 120 is fixed to the glass circuit board 100A by fastening bolts 56 into the fastening holes 55, the bolts 56 having penetrated the outer periphery of the protective cover 120. The protective cover 120 has a cover glass 121 that protects the light receiving surface of the imaging element 110 and passes incident light onto the light receiving surface. The cover glass 121 may be one or more condenser lenses.

In the imaging device 200, the glass circuit board 100A having the fastening holes 55 may be replaced with the glass circuit board 100 that does not have the fastening holes 55 (for example, see FIG. 1). In this case, the protective cover 120 may be fixed to the glass circuit board 100 by using an adhesive (not illustrated) instead of the bolts 56. Thus, the glass circuit boards 100 and 100A can be used as substrates for CMOS image sensors.

The method of using the fastening holes 55 is not limited to the attachment of the protective cover 120. For example, the fastening holes 55 may be used to assemble the glass circuit board 100A to a camera housing or the like (not illustrated).

In FIG. 15, the fastening holes 55 are opened on the front side (the top surface in FIG. 15) of the glass circuit board 100A. The opening positions of the fastening holes 55 are not limited thereto. The fastening holes 55 may be opened on the back side (the underside in FIG. 15) of the glass circuit board 100A, which is not illustrated. Alternatively the fastening holes 55 may be through holes formed between the front side and the back side of the glass circuit board 100A.

### Sixth Embodiment

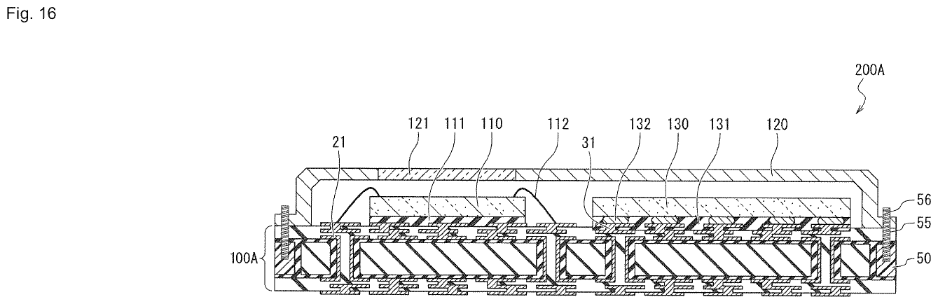

FIG. 16 is a cross-sectional view illustrating a configuration example of an imaging device 200A according to a sixth embodiment of the present disclosure. As illustrated in FIG. 15, the imaging device 200A according to the sixth embodiment of the present disclosure includes the glass circuit board 100A described in the fourth embodiment, an imaging element 110 mounted on the glass circuit board 100A, a semiconductor element 130 mounted on the glass circuit board 100A, and a protective cover 120 that is attached to the glass circuit board 100A to cover the imaging element 110.

The kind of semiconductor element 130 is not particularly limited. For example, the semiconductor element 130 is a logic IC such as a central processing unit (CPU) or the like or a memory integrated circuit (IC) such as dynamic random access memory (DRAM) or flash memory. The semiconductor element 130 is bonded on the glass circuit board 100A with an adhesive 131 and is electrically connected to the bonding pads of a first multilayer wiring 31 via solder balls or the like (e.g., flip-chip packaging).

Also in the imaging device 200A, as in the imaging device 200 described in the fourth embodiment, the glass circuit board 100A having fastening holes 55 may be replaced with the glass circuit board 100 that does not have the fastening holes 55 (for example, see FIG. 1). In this case, the protective cover 120 may be fixed to the glass circuit board 100 by using an adhesive (not illustrated) instead of bolts 56.

Also in the imaging device 200A, the method of using the fastening holes 55 is not limited to the attachment of the protective cover 120. For example, the fastening holes 55 may be used to assemble the glass circuit board 100A to a camera housing or the like (not illustrated).

Also in the imaging device 200A, the opening positions of the fastening holes 55 are not limited to the front side (the top surface in FIG. 16) of the glass circuit board 100A. The opening positions of the fastening holes 55 may be located on the back side (the underside in FIG. 16) of the glass circuit board 100A.

Alternatively the fastening holes 55 may be through holes formed between the front side and the back side of the glass circuit board 100A.

### OTHER EMBODIMENTS

While the present disclosure has been described on the basis of the embodiments and modifications, the descriptions and figures that constitute parts of the present disclosure should not be understood as limiting the present disclosure. Various alternative embodiments, examples, and operable techniques will be apparent to those skilled in the art from the present disclosure. It is needless to say that the present technique includes various embodiments that are not described herein. At least one of various omissions, substitutions, and modifications of components may be performed without departing from the gist of the embodiments and the modifications described above. Furthermore, the advantageous effects described in the present specification are merely exemplary and not intended as limiting, and other advantageous effects may be obtained.

The present disclosure can also be configured as follows.

(1) A glass circuit board including:
a glass substrate serving as a core material including a first side, a second side located opposite from the first side, an outer end face located between the first side and the second side, and a through hole penetrating between the first side and the second side;
an insulating first resin layer covering the first side;
an insulating second resin layer covering the second side;
a third resin layer that covers the inner surface of the through hole and is continuous with the first resin layer and the second resin layer;
a fourth resin layer that covers the outer end face and is continuous with the first resin layer and the second resin layer;
a first core wiring provided on the first side with the first resin layer interposed between the first core wiring and the first side;
a second core wiring provided on the second side with the second resin layer interposed between the second core wiring and the second side; and
a feed-through wiring provided on the inner surface of the through hole with the third resin layer interposed between the feed-through wiring and the inner surface.
   (2)

The glass circuit board according to (1), wherein the first resin layer, the second resin layer, the third resin layer, and the fourth resin layer are made of the same insulating resin material.

(3)

The glass circuit board according to (1) or (2), further including an embedded resin in the through hole,
wherein the feed-through wiring is located between the third resin layer and the embedded resin.
   (4)

The glass circuit board according to (3), further including a first interlayer insulating film that is provided near the first side of the glass substrate and covers the first core wiring; and
a second interlayer insulating film that is provided near the second side of the glass substrate and covers the second core wiring,
wherein the first interlayer insulating film and the second interlayer insulating film are made of the same insulating resin material as the embedded resin.
   (5)

The glass circuit board according to (3), wherein the embedded resin is made of the same insulating resin material as the third resin layer.

(6)

The glass circuit board according to (3), wherein the embedded resin is made of a conductive resin material.

(7)

The glass circuit board according to any one of (3) to (6), further including a conductive lid portion that is disposed on the opening end of the through hole and covers the embedded resin.

(8)

The glass circuit board according to (1) or (2), wherein the through hole is filled with the feed-through wiring.

(9)

The glass circuit board according to any one of (1) to (8), further including a frame that accommodates the glass substrate,
wherein the fourth resin layer fills a clearance between the frame and the outer end face of the glass substrate.
   (10)

A method for manufacturing a glass circuit board, the method including: placing a glass substrate serving as a core material in a frame, the glass substrate including a first side, a second side located opposite from the first side, an outer end face located between the first side and the second side, and a through hole penetrating between the first side and the second side;
supplying a resin material into the frame to form a first resin layer covering the first side, a second resin layer covering the second side, a third resin layer covering the inner surface of the through hole, and a fourth resin layer covering the outer end face of the glass substrate;
forming a first core wiring provided on the first side with the first resin layer interposed between the first core wiring and the first side;
forming a second core wiring provided on the second side with the second resin layer interposed between the second core wiring and the second side;
forming a feed-through wiring provided in the through hole with the third resin layer interposed between the feed-through wiring and the through hole; and cutting the frame or the fourth resin layer in the thickness direction of the glass substrate after forming the first core wiring, the second core wiring, and the feed-through wiring.
   (11)

An imaging device including: a glass circuit board; and an imaging element attached to the glass circuit board, the glass circuit board including:
a glass substrate serving as a core material including a first side, a second side located opposite from the first side, an outer end face located between the first side and the second side, and a through hole penetrating between the first side and the second side;
an insulating first resin layer covering the first side;
an insulating second resin layer covering the second side;
a third resin layer that covers the inner surface of the through hole and is continuous with the first resin layer and the second resin layer;
a fourth resin layer that covers the outer end face and is continuous with the first resin layer and the second resin layer;
a first core wiring provided on the first side with the first resin layer interposed between the first core wiring and the first side;
a second core wiring provided on the second side with the second resin layer interposed between the second core wiring and the second side; and
a feed-through wiring provided on the inner surface of the through hole with the third resin layer interposed between the feed-through wiring and the inner surface.

### REFERENCE SIGNS LIST

1 Glass substrate
1a Front side
1b Back side
1c Outer end face
11 First resin layer
12 Second resin layer
13 Third resin layer
14 Fourth resin layer
15 Embedded resin
21 First core wiring
22 Second core wiring
23 Feed-through wiring
31 First multilayer wiring
32 Second multilayer wiring
41 First interlayer insulating film
42 Second interlayer insulating film
45, 53 Embedded resin
50 Frame substrate
51 Film
52 Pocket structure
55 Fastening hole
56 Bolt
100, 100A Glass circuit board
110 Imaging element
111, 131 Adhesive
112 Bonding wire
120 Protective cover
121 Cover glass
130 Semiconductor element
200, 200A Imaging device
211, 221 Conductive lid portion
dh, dH Diameter
h Inner through hole
H Through hole

1. A glass circuit board comprising: a glass substrate serving as a core material including a first side, a second side located opposite from the first side, an outer end face located between the first side and the second side, and a through hole penetrating between the first side and the second side;
an insulating first resin layer covering the first side;
an insulating second resin layer covering the second side;
a third resin layer that covers an inner surface of the through hole and is continuous with the first resin layer and the second resin layer;
a fourth resin layer that covers the outer end face and is continuous with the first resin layer and the second resin layer;
a first core wiring provided on the first side with the first resin layer interposed between the first core wiring and the first side;
a second core wiring provided on the second side with the second resin layer interposed between the second core wiring and the second side; and
a feed-through wiring provided on the inner surface of the through hole with the third resin layer interposed between the feed-through wiring and the inner surface.

2. The glass circuit board according to claim 1, wherein the first resin layer, the second resin layer, the third resin layer, and the fourth resin layer are made of the same insulating resin material.

3. The glass circuit board according to claim 1, further comprising an embedded resin in the through hole,
wherein the feed-through wiring is located between the third resin layer and the embedded resin.

4. The glass circuit board according to claim 3, further comprising a first interlayer insulating film that is provided near the first side of the glass substrate and covers the first core wiring; and
a second interlayer insulating film that is provided near the second side of the glass substrate and covers the second core wiring,
wherein the first interlayer insulating film and the second interlayer insulating film are made of the same insulating resin material as the embedded resin.

5. The glass circuit board according to claim 3, wherein the embedded resin is made of the same insulating resin material as the third resin layer.

6. The glass circuit board according to claim 3, wherein the embedded resin is made of a conductive resin material.

7. The glass circuit board according to claim 3, further comprising a conductive lid portion that is disposed on an opening end of the through hole and covers the embedded resin.

8. The glass circuit board according to claim 1, wherein the through hole is filled with the feed-through wiring.

9. The glass circuit board according to claim 1, further comprising a frame that accommodates the glass substrate,
wherein the fourth resin layer fills a clearance between the frame and the outer end face of the glass substrate.

10. A method for manufacturing a glass circuit board, the method comprising:
placing a glass substrate serving as a core material in a frame, the glass substrate including a first side, a second side located opposite from the first side, an outer end face located between the first side and the second side, and a through hole penetrating between the first side and the second side;
supplying a resin material into the frame to form a first resin layer covering the first side, a second resin layer covering the second side, a third resin layer covering an inner surface of the through hole, and a fourth resin layer covering the outer end face of the glass substrate;
forming a first core wiring provided on the first side with the first resin layer interposed between the first core wiring and the first side;
forming a second core wiring provided on the second side with the second resin layer interposed between the second core wiring and the second side;
forming a feed-through wiring provided in the through hole with the third resin layer interposed between the feed-through wiring and the through hole; and
cutting the frame or the fourth resin layer in a thickness direction of the glass substrate after forming the first core wiring, the second core wiring, and the feed-through wiring.

11. An imaging device comprising: a glass circuit board; and
an imaging element attached to the glass circuit board,
the glass circuit board including:
a glass substrate serving as a core material including a first side, a second side located opposite from the first side, an outer end face located between the first side and the second side, and a through hole penetrating between the first side and the second side;
an insulating first resin layer covering the first side;
an insulating second resin layer covering the second side;
a third resin layer that covers an inner surface of the through hole and is continuous with the first resin layer and the second resin layer;
a fourth resin layer that covers the outer end face and is continuous with the first resin layer and the second resin layer;
a first core wiring provided on the first side with the first resin layer interposed between the first core wiring and the first side;
a second core wiring provided on the second side with the second resin layer interposed between the second core wiring and the second side; and
a feed-through wiring provided on the inner surface of the through hole with the third resin layer interposed between the feed-through wiring and the inner surface.
